(19) United States
(12) Patent Application Publication
(10) Pub. No.: US 2012/0218734 A1
(43) Pub. Date: Aug. 30, 2012

(54) Packing Member

(75) Inventor: Satoshi Fujita, Osaka (JP)

(73) Assignee: PANASONIC CORPORATION, Osaka (JP)

(21) Appl. No.: 13/406,535

(22) Filed: Feb. 28, 2012

(30) Foreign Application Priority Data
Feb. 28, 2011 (JP) 2011-042897

(51) Int. Cl. H05K 9/00

(52) U.S. Cl. 361/818

(57) ABSTRACT

A packing member is provided in which waterproofness is achieved and electromagnetic waves are blocked. The packing member has: a first member; and a second member for covering at least a part of the surface of the first member. The first member is composed of a material having a larger elastic deformability than the second member. The second member is composed of a composite material containing electrically conductive substance and is electrically connected to the surface of a base on which the first member is mounted.

### CROSS REFERENCE TO RELATED APPLICATION

The disclosure in Japanese Patent Application No. 2011-042897 filed on Feb. 28, 2011 (Heisei 23) is incorporated herein by reference.

### BACKGROUND OF THE INVENTION

1. Field of the Invention

The present invention relates to a packing member used, for example, in a lid for closing an opening of the housing of a notebook computer or the like.

2. Description of the Background Art

For example, the housing of a mobile electronic device such as a notebook computer has an opening such as a PC card slot. The opening is closed by a lid that can be opened and closed freely.

The above-mentioned mobile electronic device is used outdoors in some cases and hence can be exposed to rain. Thus, the mobile electronic device need be provided with a waterproof property of preventing water from entering the housing. Accordingly, for example, a structure is adopted that a lid whose one surface is provided with a packing is pressed against the outer surface of a housing so that the packing is pinched by the lid and the housing. For example, the packing is composed of a rubber material having flexibility and elasticity. By virtue of this, a gap between the lid and the housing is sealed with the packing so that a waterproof property is achieved.

The above-mentioned mobile electronic device is requested to have the property of blocking the transmission of electromagnetic waves to the inside or to the outside of the mobile electronic device. Nevertheless, the rubber material used in the above-mentioned packing does not have electric conductivity. Thus, electromagnetic waves are not blocked in the seal part of the gap between the lid and the housing.

On the other hand, when an electrically conductive material is pinched between the lid and the housing at least each surface of which has electrically conductive substance, electromagnetic waves are blocked. An example of this electrically conductive material is a rubber material containing metal filler. Nevertheless, the rubber material containing metal filler has a higher rubber hardness than the above-mentioned rubber material constituting a packing. As a result, when the electrically conductive material is pinched by the lid and the housing, close contact to be formed between the electrically conductive material and the housing outer surface is unsatisfactory so that obtained waterproofness is unsatisfactory.

Here, Japanese Laid-Open Patent Publication No. H11-317589 discloses a configuration in order that waterproofness and electromagnetic-wave blocking should be achieved, a waterproof packing and an electrically conductive member composed of a metallic claw provided together with the waterproof packing are employed simultaneously. Nevertheless, in this configuration, the metal claw and the electrically conductive housing are pressed against each other and thereby brought into close contact and conduction with each other so that electromagnetic waves are blocked. Thus, the electric conduction easily becomes unsatisfactory. Further, since the electrically conductive member is provided separately, an increase is caused in the number of components and in the number of fabrication process steps. This causes an increase in the fabrication cost.

Further, Japanese Laid-Open Patent Publication No. H10-256770 discloses a shielding and waterproof member having a waterproof property and an electromagnetic-wave blocking property. The shielding and waterproof member is constructed such that a shielding member having electric conductivity and a packing member are provided in parallel on a lid.

Nevertheless, in the disclosure in Japanese Laid-Open Patent Publication No. H10-256770, unless the mechanical flexibilities of the shielding member and the packing member agree with each other, the amounts of deformation at the position where the housing body abuts against the shielding and waterproof member are different from each other. As described above, since the waterproof packing has higher mechanical flexibility, in the configuration that the shielding member and the packing member are arranged in parallel, the amount of deformation of the packing member in the shielding and waterproof member becomes large and hence the property of following the amount of deformation is unsatisfactory in the shielding member. This causes a problem of unsatisfactory shielding property. Thus, in the contact surface between the shielding and waterproof member and the housing, uniform waterproofness and electromagnetic-wave blocking become difficult to be achieved.

### SUMMARY OF THE INVENTION

Thus, an object of the present invention is to provide a packing member in which waterproofness is achieved and electromagnetic waves are blocked.

The present invention relates to a packing member for blocking electromagnetic waves. The packing member has: a first member; and a second member for covering at least a part of the surface of the first member. The first member is composed of a material having a larger elastic deformability than the second member. The second member is composed of a composite material containing electrically conductive substance and is electrically connected to the surface of a base on which the first member is mounted.

In the above-mentioned packing member, the first member and the second member may be embedded in a recess provided in the base.

The first member and the second member may be stacked with each other in a direction that the first member is mounted on the base.

Further, the present invention relates to a lid for opening and closing an opening of a housing of an electronic device. The lid is provided with the above-mentioned packing member. The above-mentioned housing having electric conductivity abuts against the second member.

The above-mentioned lid may further be provided with a recess into which the first member and the second member are embedded.

The housing may be convex at a part abutting against the second member.

It is preferable that the first member and the second member are stacked with each other in a direction that the housing abuts against the second member.

When the lid and the housing are sealed by using the packing member according to the present invention, waterproofness is achieved and electromagnetic waves are blocked.

These and other objects, features, aspects, and effects of the present invention will become clearer on the basis of the following detailed description with reference to the accompanying drawings.

### BRIEF DESCRIPTION OF THE DRAWINGS

FIG. 1 is a perspective view of a housing and a lid sealed with a packing member according to an embodiment of the present invention;

FIG. 2 is an enlarged view of part A of a housing shown in FIG. 1 in a state that a lid is opened;

FIG. 3A is a sectional view showing an example of a packing member;

FIG. 3B is a sectional view showing another example of a packing member;

FIG. 4A is a sectional view of a lid taken along line X-X in FIG. 1;

FIG. 4B is a sectional view of a part corresponding to FIG. 4A in a state that a lid is closed completely; and

FIG. 5 is a sectional view of a lid according to another modification.

### DESCRIPTION OF THE PREFERRED EMBODIMENTS

### Embodiment

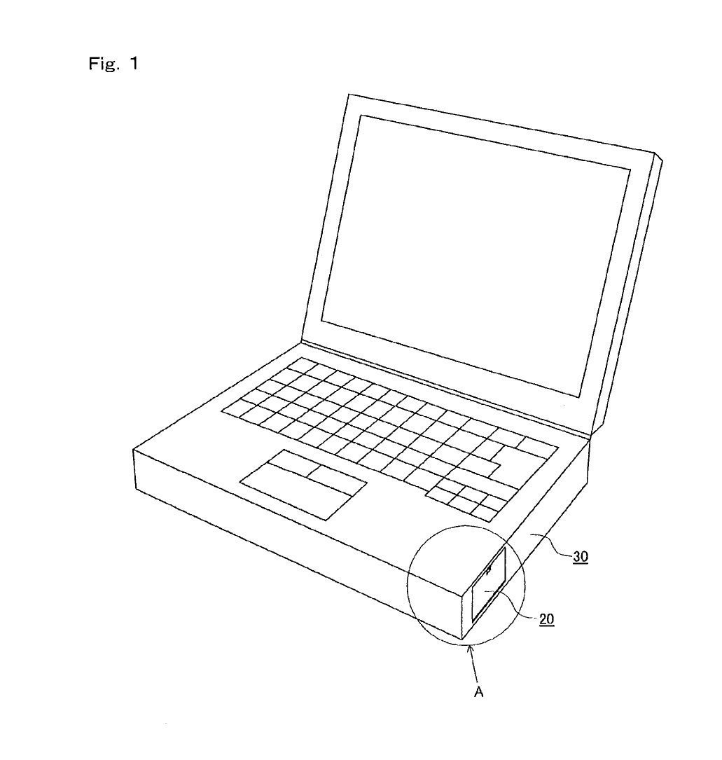

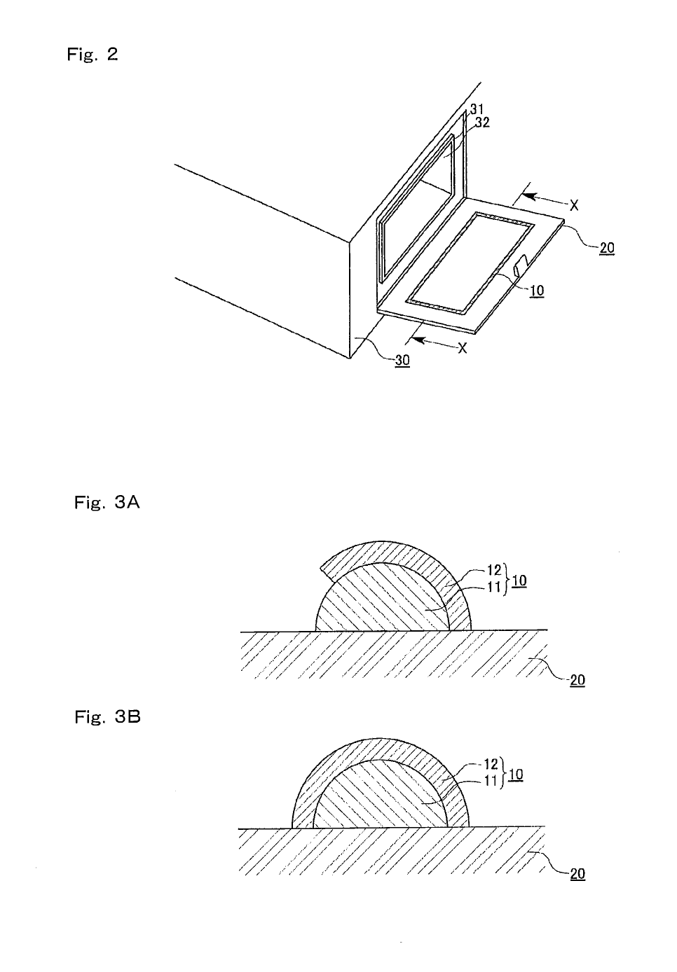

FIG. 1 is a perspective view of a housing and a lid sealed with a packing member according to an embodiment. FIG. 2 is an enlarged view of part A of the housing shown in FIG. 1 in a state that the lid is opened.

In an example, a packing member 10 according to the present embodiment is provided in a lid 20 for opening and closing an opening 32 of a housing 30. The lid 20 is linked to the housing 30 through a hinge in a manner that opening and closing are allowed freely. At a completely closed position, the lid 20 is locked to the housing 30 (the state shown FIG. 1).

FIG. 3A is a sectional view showing an example of a packing member.

An example of the packing member 10 is described below with reference to FIG. 3A. In the packing member 10, when the lid 20 and the housing 30 (not shown) abuts against each other, waterproofness is achieved. The packing member 10 has: a first member 11; and a second member 12 for partly covering the surface of the first member 11. Then, when the base 20 and the housing 30 are electrically connected to each other through the second member 12 whose surface has electric conductivity, electromagnetic-wave blocking is achieved. Here, in the present specification, the term “packing” indicates both of a seal for sealing a moving part so as to achieve waterproofness and a seal for sealing a static part so as to achieve waterproofness.

The first member 11 is provided on a base (corresponding to the lid, in the present embodiment) 20, and plays a role of imparting flexibility to the packing member 10. Thus, a configuration is preferable that a material having a larger elastic deformability than the second member 12 is selected for the first member 11 so that when the lid (the base 20) completely closes the opening 32, restorability is obtained. In an example, polyurethane rubber is employed preferably.

The second member 12 is stacked on the first member 11 in a direction (the vertical direction in FIG. 3A) that the flat face abuts against the packing member 10. The second member 12 is in close contact with the base 20. Further, the second member 12 is stacked on the first member 11 in a manner that a part of the second member 12 protrudes from the base 20. This allows the packing member 10 to be reliably in close contact with the housing 30 (not shown) when the base 20 is closed completely. Here, in an example, the second member 12 is preferably fabricated from a compound material of silicone rubber, nitrile rubber, chloroprene rubber, or the like containing electrically conductive substance. Among these, silicone rubber is remarkably preferable because of its excellence in the points of heatproofness, waterproofness, and repetition durability.

Here, the thickness of the second member 12 is designed to be thinner than that of the first member 11 in order that when the packing member 10 is compressed in association with a situation that the base 20 is closed completely, the second member 12 should follow the elastic deformation of the first member 11.

In an example, in the present embodiment, such a design is adopted that the thickness of the first member 11 is approximately 1.0 mm, the thickness of the second member 32 is approximately 0.5 mm, and the widths of the first member 11 and the second member 12 are 2.5 mm each. Here, the thicknesses of the first member 11 and the second member 12 may be adjusted appropriately to an optimal value in accordance with the hardness of the material constituting each member and the shape and the dimensions of the recess 21.

The second member 12 plays a role of imparting electric conductivity to the surface of the packing member 10, and is composed of a composite material containing electrically conductive substance. Further, when one end (an end part located on the right-hand side in FIG. 3A) of the second member 12 contacts with the surface of the base 20 with electric conductivity, the second member 12 and the base 20 are electrically connected to each other. Here, the base 20 is formed from an electrically conductive member (metal or the like) or, alternatively, formed by fabricating a metal thin film onto the surface of an electrically non-conductive member (such as a resin-molded member).

The first member 11 and the second member 12 are stacked with each other in a direction (the vertical direction in FIG. 3A) that the first member is mounted on the base 20.

The other end (an end part located on the left-hand side in FIG. 3A) of the second member 12 is not in contact with the lid 20. Thus, when the lid (the base) is closed completely so that the packing member 10 is compressed in the vertical direction in FIG. 3A, the first member 11 is deformed such as to enter the gap between the other end of the second member 12 and the base 20 so that the amount of deformation of the first member 11 is absorbed. Here, as shown in FIG. 3B, the packing member 10 may employ a configuration that both ends of the second member 12 contact with the surface of the base 20.

When the base 20 is closed, a flat part (not shown) of the housing 30 abuts against the packing member 10 arranged in the base 20.

When the flat part of the housing 30 is pressed against the base 20, the flat part 30 compresses and deforms the second member 12. As a result, the contact area between the flat part 30 and the second member 12 is increased so that an electromagnetic-wave blocking effect is enhanced.

At that time, in the first member 11, in order that the amount of compressive deformation of the flat part should be absorbed, for example, as shown in FIG. 3A, the amount of deformation of the first member 11 protrudes into the gap formed by separation between the second member 12 and the base 20. Alternatively, as shown in FIG. 3B, the packing member 10 is compressed and deformed along the flat part. The second member 12 is expanded so as to follow the amount of push-in associated with the pressing of the flat part. In other words, the packing member 10 has elastic deformability in the first member 11 that follows the push-in of the flat part and tensile deformability in the second member 12 that follows the amount of elastic deformation of the first member 11.

Thus, in the present embodiment, as described above, the thickness of the second member is designed to be thinner than that of the first member. In an example, the material constituting the first member 11 is selected to be one having a rubber hardness of 35 and the material constituting the second member 12 is selected to be one having a rubber hardness of 53 to 60 (preferably, 55).

Further, in the present embodiment, a configuration may be adopted that the packing member is embedded in a recess.

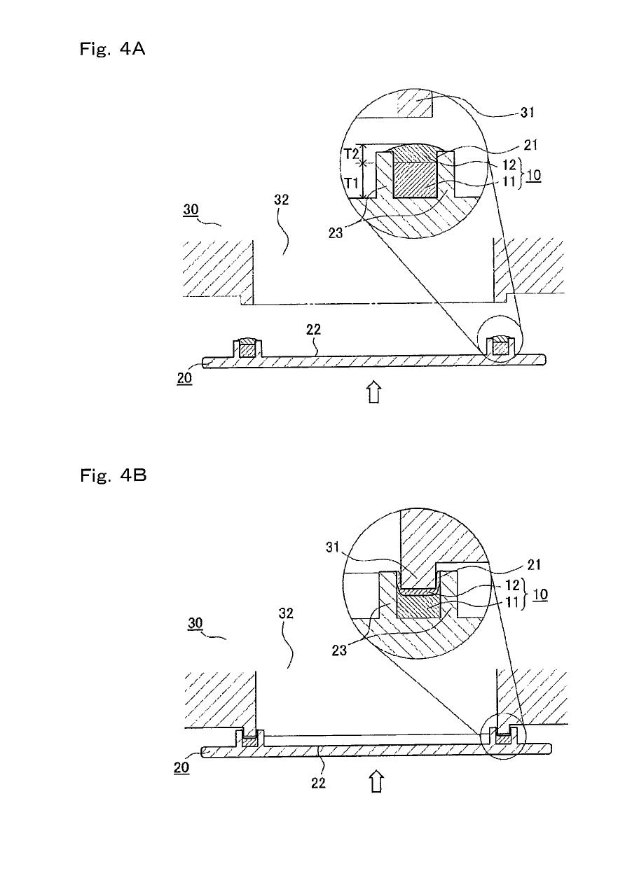

FIG. 4A is a sectional view of a lid taken along line X-X in FIG. 2.

As described above, in an example, the packing member 10 according to the present embodiment is provided on the lid 20. When the lid 20 is closed completely, the housing 30 abuts against the packing member 10. More specifically, as shown in FIG. 4A, the housing 30 has a protrusion 31 and the protrusion 31 presses the packing member 10.

Here, for the purpose of ensuring waterproofness and dripproofness (a so-called sealing property) between the lid 20 and the housing 30, a configuration is preferable that the packing member 10 hardly drops from the lid 20. Thus, the packing member 10 is embedded in the recess 21 in a manner of being in close contact with the inner wall of the recess 21.

The recess 21 is formed from a member having electric conductivity or, alternatively, formed by fabricating a metal thin film onto the surface of an electrically non-conductive member. The recess 21 is provided near the outer periphery on the inner side of an opposed face 22 (an upper end face in FIG. 4A) in the lid 20 on the side opposite to the opening 32 of the housing 30.

In further details, the opposed face 22 of the lid 20 is provided with a pair of side walls 23 protruding from the opposed face 22. Then the recess 21 is formed by the pair of side walls 23 and the part of the opposed face 22 located between the pair of side walls 23. Further, in order to correspond to the protrusion 31 provided in the outer periphery part of the opening 32 of the housing 30, the recess 21 is formed such that the cross section taken in parallel to the opposed face 22 has a rectangular ring shape.

Here, in order that electromagnetic waves should be absorbed or reflected, for example, the lid 20 and the housing 30 are fabricated from an electrically conductive member (such as a metallic material) or, alternatively, fabricated from an electrically non-conductive member (such as a resin-molded member) in which a metal thin film is formed in the surface of the part where electric conductivity is required. Further, in the inside of the opening 32 of the housing 30, a card slot, a connector, an antenna circuit, or the like (not shown) is provided solely or in combination.

The first member 11 is provided on the bottom side of the recess 21 relative to the second member 12, and is in close contact with the inner wall of the recess 21. Further, although details are described later, in the present embodiment, the first member 11 is formed by applying the material onto the recess 21 and plays a role of imparting flexibility to the packing member 10. Thus, for the first member 11, a material is selected that has a larger elastic deformability than the second member 12. Further, a configuration is preferable that when the lid 20 completely closes the opening 32, the first member 11 has restorability. Thus, in an example, in the first member 11, polyurethane rubber is employed preferably.

The second member 12 is stacked on the first member 11 in a direction (the vertical direction in FIG. 4A) that a protrusion 41 abuts against the packing member 10. The second member 12 is in close contact with the inner wall of the recess 21. Further, the second member 12 is stacked on the first member 11 in a manner that a part of the second member 12 protrudes from the recess 21. This allows the packing member 10 to be reliably in close contact with the housing 30 when the lid 20 is closed completely. Here, in an example, the second member 12 is preferably fabricated from a compound material of silicone rubber, nitrile rubber, chloroprene rubber, or the like containing electrically conductive substance. Among these, silicone rubber is remarkably preferable because of its excellence in the points of heatproofness, waterproofness, and repetition durability.

Here, the thickness T2 of the second member 12 is designed to be thinner than the thickness T1 of the first member 11 in order that when the packing member 10 is compressed in association with a situation that the lid 20 is closed completely, the second member 12 should follow the elastic deformation of the first member 11.

In an example, in the present embodiment, such a design is adopted that the thickness T1 of the first member 11 is approximately 1.0 mm, the thickness T2 of the second member 32 is approximately 0.5 mm, and the widths of the first member 11 and the second member 12 are 2.5 mm each. Here, the thicknesses of the first member 11 and the second member 12 may be adjusted appropriately to an optimal value in accordance with the hardness of the material constituting each member and the shape and the dimensions of the recess 21.

Further, as described above, the first member and the second member are sequentially injected into the recess 21 by a dispenser, and then heated and hardened so that the packing member is obtained. This avoids a situation that the low-viscosity material present immediately after the injecting spreads unintentionally.

Further, the first member 11 and the second member 12 present in the state of low-viscosity material before the hardening spreads over the surface of the inner wall of the recess 21 without a free space. In this state, the first member 11 and the second member 12 are hardened. Thus, the first member 11 and the second member 12 are brought into firm close contact with the inner wall of the recess 21. Here, for example, a sheet obtained by stacking the first member and the second member with, in between, an adhesive layer such as silicone resin having viscoelasticity may be punched so that the packing member may be obtained. Then, the obtained packing member may be fitted in the recess 21.

Further, at the time of closing the lid 20, the protrusion 31 is pushed into the recess 21. This permits easy alignment between the housing 30 and the lid 20. Further, when the lid 20 is closed completely, the protrusion 31 is fitted into the recess 21. Thus, the fitting part between the lid 20 and the housing 30 becomes rigid. Accordingly, even when an external force in a direction transverse to the direction of fitting of the protrusion 31 into the recess 21 acts on the lid 20 and the housing 30, the protrusion 31 does not drop from the recess 21. Here, the protrusion 31 is provided along the entire circumference in the peripheral part of the opening 32 of the housing 30 such as to oppose the recess 21 when the lid 20 is closed completely.

FIG. 4B is a sectional view of a part corresponding to FIG. 4A in a state that the lid is closed completely.

When the lid 20 is closed, the protrusion 31 of the housing 30 abuts against the packing member 10 embedded in the recess 21. The width of the protruding part of the protrusion 31 is formed slightly smaller than that of the recess part of the recess 21. Thus, a gap is present between the protrusion 31 and the recess 21.

When a pressure is applied onto the lid 20 in the direction of an arrow in FIG. 4B, the protrusion 31 enters the recess 21 and the second member 12 is pushed into the gap between the protrusion 31 and the recess 21. As a result, the contact area between the protrusion 31 and the second member 12 is increased so that the electromagnetic-wave blocking effect is enhanced. Here, in the present embodiment, as an example, the protrusion 31 is pushed into the recess 21 until the gap between the tip of the protrusion 31 and the bottom of the recess 21 becomes 1.0 to 1.1 mm.

At that time, in order that the amount of push-in of the protrusion 31 should be absorbed, the length of the first member 11 measured from the bottom of the recess 21 to the tip of the protrusion 31 varies and the second member 12 is expanded such as to follow the amount of push-in of the protrusion 31. In other words, the packing member 10 has elastic deformability in the first member 11 that follows the push-in of the protrusion 31 and tensile deformability in the second member 12 that follows the amount of elastic deformation of the first member 11.

Thus, in the present embodiment, as described above, the thickness of the second member is designed to be thinner than that of the first member. In an example, the material constituting the first member 11 is selected to be one having a rubber hardness of 35 and the material constituting the second member 12 is selected to be one having a rubber hardness of 53 to 60 (preferably, 55).

As such, in a state that either the flat face of the housing 30 or the tip of the protrusion 31 is in close contact with the packing member 10, the lid 20 is closed. As described above, in the present embodiment, in the base 20 or the recess 21, the first member 11 and the second member 12 are stacked with each other in a direction that the protrusion 31 abuts against the packing member 10. Thus, when the flat face of the housing 30 is pressed against the base 20 or, alternatively, the protrusion 31 is pushed into the recess 21, the contact area between the protrusion 31 and the second member 12 is increased. This provides an excellent waterproof property and an excellent electromagnetic-wave blocking property.

Further, as described above, the packing member 10 is formed by applying the first member and the second member by a dispenser and then hardening the materials. Thus, the packing member 10 is in close contact with the flat face of the base 20 or with the inner wall of the recess 21. Further, the first member 11 and the second member 12 are in close contact with each other. Thus, even when the lid 20 is opened and closed repeatedly, the packing member 10 does not drop from the recess 21 in the flat face of the base 20 and the first member 11 and the second member 12 are not peeled off from each other at joint interface.

Further, when the lid 20 is closed completely, the second member 12 in the packing member 10 is in contact with both of the base 20 or the recess 21 of the lid 20 and the housing 30 or the protrusion 31 of the housing 30. By virtue of this, the lid 20 and the housing 30 are in electric conduction with each other through the second member 12. Thus, in the packing member 10, electromagnetic waves are blocked. Here, in order that electric conduction should be established between the lid 20 and the housing 30, for example, electric conduction processing may be applied on a side of the housing 30 that is opposite to the lid 20, and then electric conduction processing may be applied also on a side of the recess 21 that is in contact with the second member 12. Alternatively, electric conduction processing may be applied on a surface of the lid 20 that is opposite to the housing 30, and then electric conduction processing may be applied also on a surface of the protrusion 31 that is in contact with the second member 12.

As described above, when the lid 20 and the housing 30 are sealed by using the packing member 10 according to the present embodiment, waterproofness is achieved and electromagnetic waves are blocked.

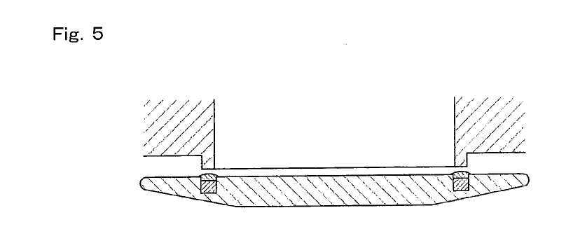

Here, as shown in FIG. 5, the recess of the lid according to the embodiment of the present invention may be constructed from a groove provided in the body inner surface. This configuration avoids the necessity of the pair of side walls in the opposed face of the lid.

Here, in the present embodiment, the recess and the packing member have been provided in the lid while the protrusion has been provided in the housing. However, employable configurations are not limited to this. That is, the recess and the packing member may be provided in the housing while the protrusion may be provided in the lid.

Further, in the present embodiment, the protrusion has been provided in the housing. However, such a protrusion may be not provided. For example, when a configuration is employed that the packing member is embedded in the recess such that a part of the packing member protrudes from the recess, the outer surface of the housing on the side contacting with the packing member may be formed in a planar shape.

Further, in the present embodiment, the packing member is embedded in the recess such that a part of the packing member protrudes. However, employable configurations are not limited to this. For example, the packing member may be formed in a size capable of being accommodated in the recess. Then, in correspondence to this, in the protrusion, the dimension in the direction of abutting against the recess may be designed longer.

Further, in the present embodiment, the application of the packing member has been the fitting of a housing and a lid. However, the present invention is not limited to this particular application. For example, when a housing is constructed from an assembly of a plurality of components, the packing member according to the present embodiment may be used in each interface of fitting of the components.

In the present embodiment, the packing member has been used in the housing of a notebook computer. However, the present invention is not limited to this particular application. For example, the present invention may be employed in the housing of an electronic device of diverse kind such as a portable phone.

For example, the present invention may be employed as a packing member used for fit-in between the housing of an electronic device and a lid for opening and closing an opening provided in the housing.

Details of the present invention have been described above. However, the above-mentioned description is completely illustrative from every point of view, and does not limit the scope of the present invention. Obviously, various improvements and modifications can be performed without departing from the scope of the present invention.

What is claimed is:

1. A packing member comprising:
a first member; and
a second member for covering at least a part of a surface of the first member, wherein
the first member is composed of a material having a larger elastic deformability than the second member, and wherein
the second member is composed of a composite material containing electrically conductive substance and is electrically connected to a surface of a base on which the first member is mounted.

2. The packing member as claimed in claim 1, wherein the first member and the second member are embedded in a recess provided in the base.

3. The packing member as claimed in claim 1, wherein the first member and the second member are stacked with each other in a direction that the first member is mounted on the base.

4. The packing member as claimed in claim 2, wherein the first member and the second member are stacked with each other in a direction that the first member is mounted on the base.

5. A lid for opening and closing an opening of a housing of an electronic device, the lid comprising
a packing member as claimed in claim 1, wherein
the housing having electric conductivity abuts against the second member.

6. The lid as claimed in claim 5, further comprising a recess in which the first member and the second member are embedded.

7. The lid as claimed in claim 6, wherein the housing is convex at a part abutting against the second member.

8. The lid as claimed in claim 5, wherein the first member and the second member are stacked with each other in a direction that the housing abuts against the second member.

9. The lid as claimed in claim 6, wherein the first member and the second member are stacked with each other in a direction that the housing abuts against the second member.

10. The lid as claimed in claim 7, wherein the first member and the second member are stacked with each other in a direction that the housing abuts against the second member.
